(19) United States
(12) Patent Application Publication
(10) Pub. No.: US 2025/0212424 A1
(43) Pub. Date: Jun. 26, 2025

(54) SEMICONDUCTOR STRUCTURE WITH MIM CAPACITOR AND FABRICATING METHOD OF THE SAME

(71) Applicant: UNITED MICROELECTRONICS CORP., Hsin-Chu City (TW)

(72) Inventors: Da-Jun Lin, Kaohsiung City (TW); Bin-Siang Tsai, Changhua County (TW); Fu-Yu Tsai, Tainan City (TW); Chung-Yi Chiu, Tainan City (TW)

(73) Assignee: UNITED MICROELECTRONICS CORP., Hsin-Chu City (TW)

(21) Appl. No.: 18/408,602

(22) Filed: Jan. 10, 2024

(30) Foreign Application Priority Data
Dec. 20, 2023 (TW) 112149793

(51) Int. Cl. H01L 29/94; H01L 21/764; H01L 27/06; H01L 29/417; H01L 29/66

(52) U.S. Cl. CPC H10D 1/665; H01L 21/764; H10D 1/047; H10D 64/254; H10D 84/811

(57) ABSTRACT

A semiconductor structure with an MIM capacitor includes a first transistor. The first transistor includes a source and a drain. An interlayer dielectric layer covers the first transistor. A source plug penetrates the interlayer dielectric layer and contacts the source. A drain plug penetrates the interlayer dielectric layer and contacts the drain. A metal interlayer dielectric layer covers the interlayer dielectric layer. An MIM capacitor is disposed in the interlayer dielectric layer and the metal interlayer dielectric layer.

### BACKGROUND OF THE INVENTION

### 1. Field of the Invention

The present invention relates to a metal-insulator-metal (MIM) capacitor, and in particular to a semiconductor structure using an air gap to form a deep trench of the MIM capacitor and a manufacturing method of the same.

### 2. Description of the Prior Art

MIM capacitors are not only used to filter noise in radio frequency circuits, or as load components in digital circuits, it is also widely used in general integrated circuit and circuit board manufacturing processes. In recent years, with the development of semiconductor integrated circuit process technology, the minimum width of devices on semiconductor substrates has gradually become smaller; therefore the density of integrated circuits per unit area is increased.

Due to the increase in the density of memory cell integrated circuits, the space occupied by a capacitor per unit area for charge storage will become smaller. Therefore, it is necessary to develop capacitors with small size but high capacitance. Therefore, how to form MIM capacitors with higher capacitance under high density has become a goal for semiconductor field.

### SUMMARY OF THE INVENTION

In view of this, the present invention provides a semiconductor structure with an MIM capacitor and a fabricating method thereof in order to form an MIM capacitor with high capacitance.

According to a preferred embodiment of the present invention, a semiconductor structure with an MIM capacitor includes a first transistor, wherein the first transistor includes a source and a drain. An interlayer dielectric layer covers the first transistor. A source plug penetrates the interlayer dielectric layer and contacts the source. A drain plug penetrates the interlayer dielectric layer and contacts the drain. A metal interlayer dielectric layer covers the interlayer dielectric layer. An MIM capacitor is disposed in the interlayer dielectric layer and the metal interlayer dielectric layer.

According to another preferred embodiment of the present invention, a semiconductor structure with an MIM capacitor includes a first transistor and an MIM capacitor disposed above the first transistor, wherein the MIM capacitor includes a first stepped profile.

According to yet another preferred embodiment of the present invention, a fabricating method of a semiconductor structure with an MIM capacitor includes provide a transistor, wherein an interlayer dielectric layer and a first metal interlayer dielectric layer cover the transistor from bottom to top. Next, the first metal interlayer dielectric layer and the interlayer dielectric layer are etched to form a recess on a gate of the transistor. Later, a dielectric layer is formed to fill part of the recess and the dielectric layer seals up an opening of the recess to form an air gap. Subsequently, a second metal interlayer dielectric layer is formed to cover the first metal interlayer dielectric layer. The second interlayer dielectric layer and the dielectric layer are etched to form a trench, wherein the trench connects the air gap, and the trench and the air gap form a deep trench. Finally, an MIM capacitor is formed to fill in the deep trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 depict a fabricating method of a semiconductor structure with an MIM capacitor according to the first preferred embodiment of the present invention, wherein:

FIG. 1 depicts a substrate with numerous transistors thereon;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4;

FIG. 6 is a fabricating stage in continuous of FIG. 5; and

FIG. 7 is a fabricating stage in continuous of FIG. 6.

FIG. 8 to FIG. 9 depict a fabricating method of a semiconductor structure with an MIM capacitor according to a second preferred embodiment of the present invention, wherein:

FIG. 8 depicts a fabricating stage of a deep trench; and

FIG. 9 is a fabricating stage in continuous of FIG. 8.

### DETAILED DESCRIPTION

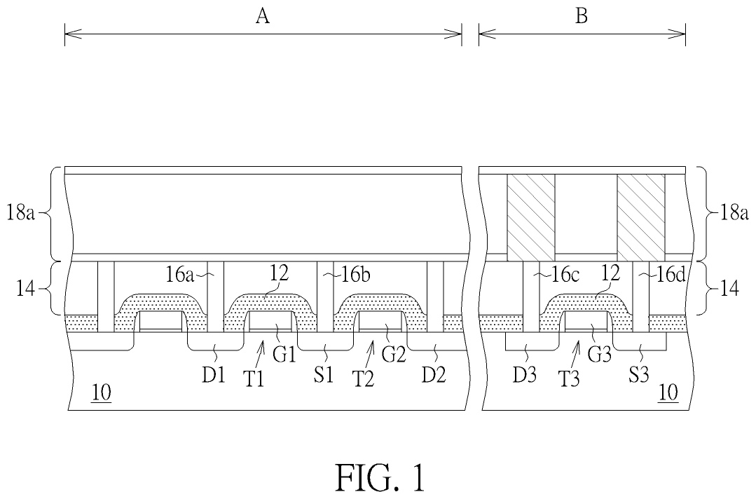

FIG. 1 to FIG. 7 depict a fabricating method of a semiconductor structure with an MIM capacitor according to the first preferred embodiment of the present invention.

As shown in FIG. 1, a substrate 10 is provided. A capacitor region A and a circuit region B are defined on the substrate 10. A first transistor T1 and a second transistor T2 are disposed on the substrate 10 in the capacitor region A. A third transistor T3 is disposed on the substrate 10 in the circuit region B. The first transistor T1 includes a first gate G1, a first source S1 and a first drain D1. The first source S1 and the first drain D1 are respectively embedded in the substrate 10 at two sides of the first gate G1. The second transistor T2 includes a second gate G2, the first source S1 and a second drain D2. The first source S1 and the second drain D2 are respectively disposed in the substrate 10 at two sides of the second gate G2. That is, the first source S1 is a common source of the first transistor T1 and the second transistor T2. The third transistor T3 includes a third gate G3, a third source S3 and a third drain D3. The third source S3 and the third drain D3 are respectively disposed in the substrate 10 at two sides of the third gate G3. An etching stop layer 12 covers the first transistor T1, the second transistor T2 and the third transistor T3. An interlayer dielectric layer 14 covers the etching stop layer 12. A first source plug 16b, a first drain plug 16a, a third source plug 16d and a third drain plug 16c respectively penetrate the interlayer dielectric layer 14 and the etching stop layer 12. The first source plug 16b contacts and electrically connects to the first source S1, The first drain plug 16a contacts and electrically connects to the first drain D1. The third source plug 16d contacts and electrically connects to the third source S3. The third drain plug 16c contacts and electrically connects to the third drain D3. A first metal interlayer dielectric layer 18a covers the interlayer dielectric layer 14.

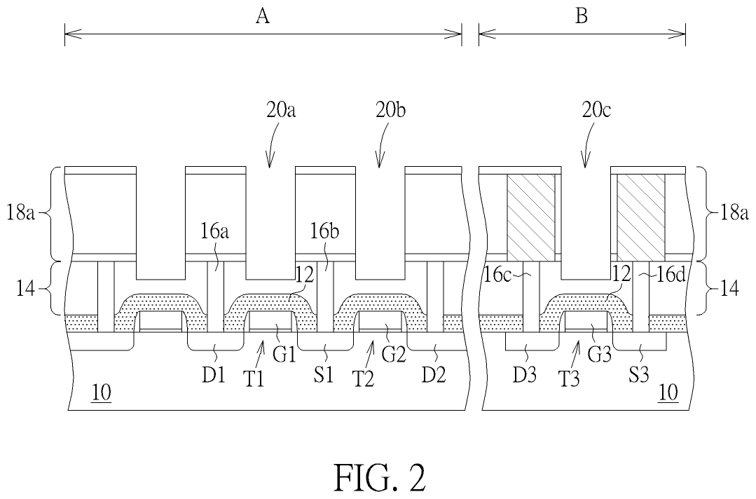

As shown in FIG. 2, the first metal interlayer dielectric layer 18a and the interlayer dielectric layer 14 are etched to form a first recess 20a on a first gate G1 of the first transistor T1, a second recess 20b on a second gate G2 of the second transistor T2, and a third recess 20c on a third gate G3 of the third transistor T3. The bottom of the first recess 20a, the bottom of the second recess 20b and the bottom of the third recess 20c are entirely in the interlayer dielectric layers 14. That is, the etching stop layer 12 is not etched during the etching process of the first metal interlayer dielectric layer 18a and the interlayer dielectric layer 14.

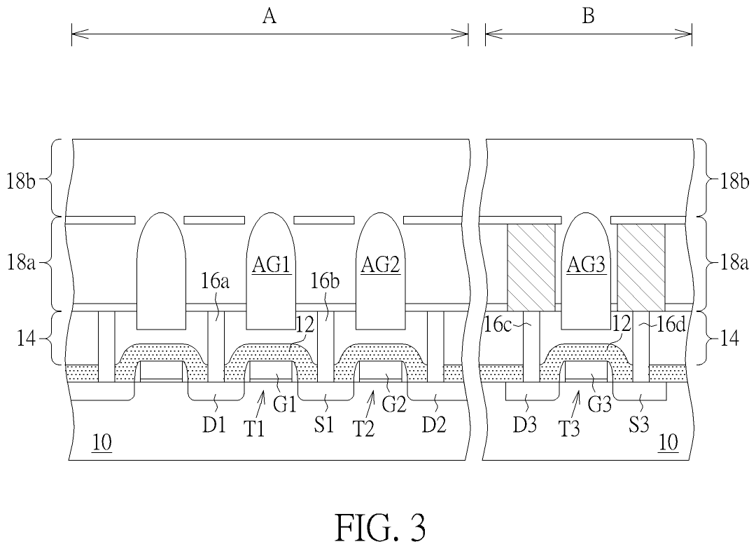

As shown in FIG. 3, a dielectric layer 18b is formed to fill in part of the first recess 20a, part of the second recess 20b and part of the third recess 20c. The dielectric layer 18b respectively seals up the opening of the first recess 20a, the opening of the second recess 20b and the opening of the third recess 20c to form a first air gap AG1, a second air gap AG2 and a third air gap AG3. The first air gap AG1 is disposed directly on the first gate G1, the second air gap AG2 is disposed directly on the second gate G2, and the third air gap AG3 is disposed directly on the third gate G3.

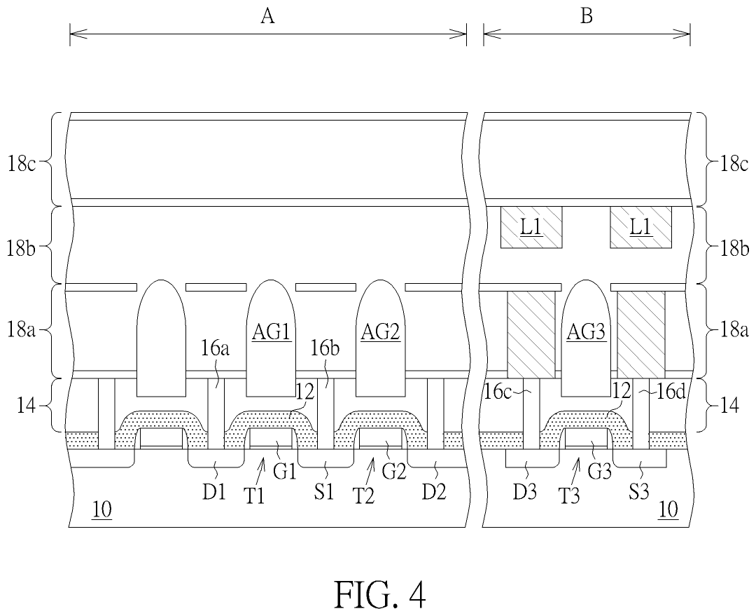

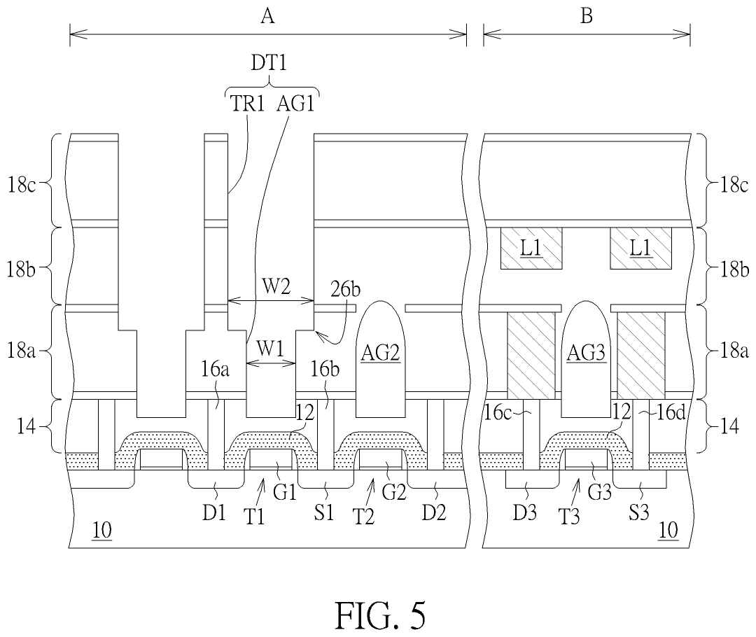

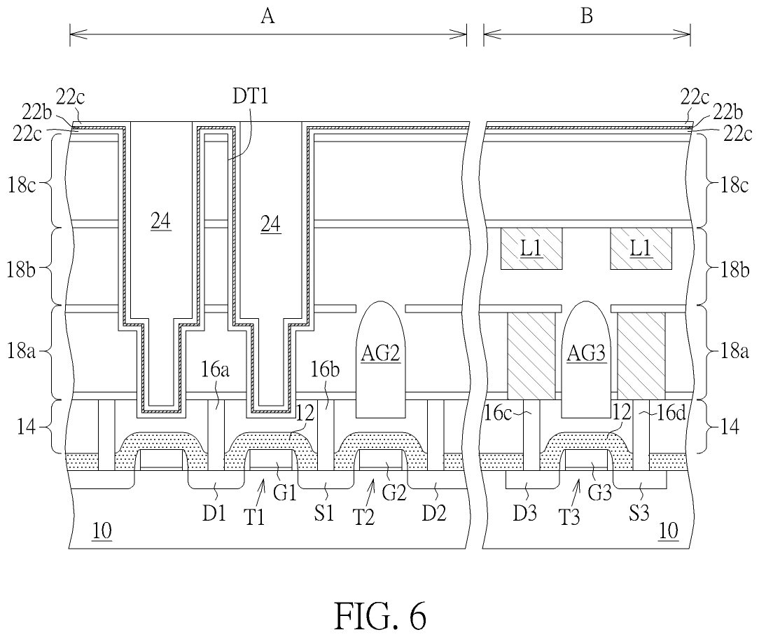

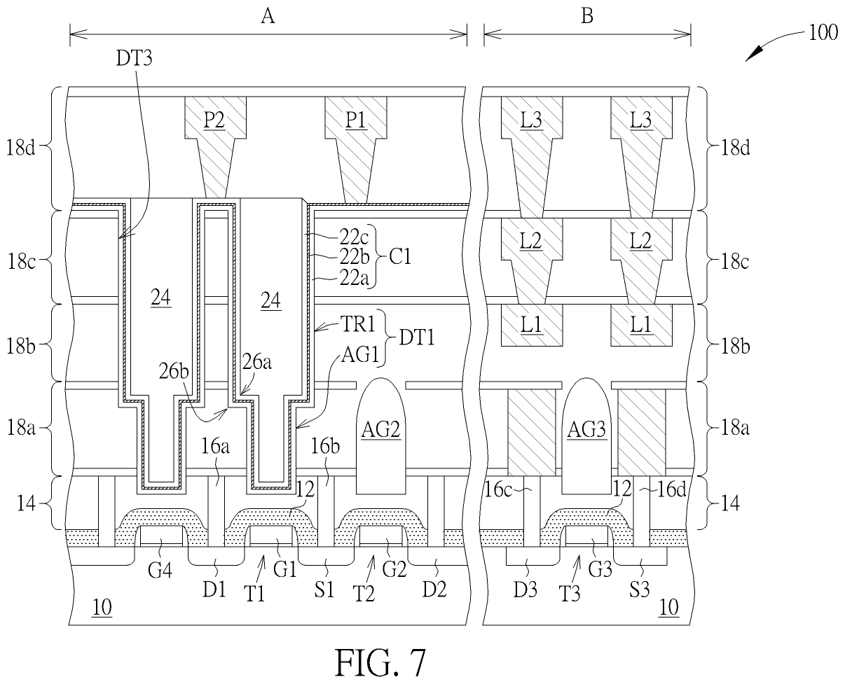

As shown in FIG. 4, a conductive line L1 is formed in dielectric layer 18b of circuit region B. Later, a second metal interlayer dielectric layer 18c is formed to cover the dielectric layer 18b and the first metal interlayer dielectric layer 18a. As shown in FIG. 5, the second metal interlayer dielectric layer 18c and the dielectric layer 18b are etched to form a trench TR1. The trench TR1 connects to the first air gap AG1, and the trench TR1 and the first air gap AG1 form a deep trench DT1. In the first preferred embodiment, the width W2 of the trench TR1 is greater than the width W1 of the first air gap AG1. When etching the second metal interlayer dielectric layer 18c and the dielectric layer 18b, the depth of the trench TR1 can be controlled by the total etching time, or by an end point detection mode. As shown in FIG. 6, a bottom electrode 22a, a capacitor dielectric layer 22b and a top electrode 22c are sequentially formed to cover the deep trench DT1 and the second metal interlayer dielectric layer 18c. Then, a silicon oxide layer 24 is formed to fill the deep trench DT1. As shown in FIG. 7, the bottom electrode 22a, the capacitor dielectric layer 22b and the top electrode 22c in the circuit region B are removed and part of the top electrode 22c on the second metal interlayer dielectric layer 18c in the capacitor region A is removed. At this time, the bottom electrode 22a, the capacitor dielectric layer 22b and the top electrode 22c remained in the deep trench DT1 and on the second metal interlayer dielectric layer 18c form an MIM capacitor C1. Then, conductive lines L2 are formed in the second metal interlayer dielectric layer 18c within the circuit region B. Conductive lines L2 contact conductive lines L1. Next, a third metal interlayer dielectric layer 18d is formed to cover the second metal interlayer dielectric layer 18c. After that, a bottom electrode plug P1, a top electrode plug P2 and conductive lines L3 are formed in the third metal interlayer dielectric layer 18d. The bottom electrode plug P1 contacts the bottom electrode 22a, and the top electrode plug P2 contacts the top electrode 22c. Conductive lines L3 contact conductive lines L2. Now, a semiconductor structure 100 with an MIM capacitor is completed.

The etching stop layer 12 is preferably a nitrogen-containing material layer, such as silicon nitride, silicon oxynitride or silicon oxycarbonitride (SiOCN). The dielectric layer 18b, the interlayer dielectric layer 14, the first metal interlayer dielectric layer 18a, the second metal interlayer dielectric layer 18c and the third metal interlayer dielectric layer 18d respectively include silicon oxide, silicon nitride, silicon carbonitride (SiCN), silicon oxynitride or silicon oxycarbonitride, etc.

The top electrode 22c and bottom electrode 22a respectively include tantalum nitride, titanium nitride, tantalum or titanium. The capacitor dielectric layer 22b includes aluminum oxide, zirconium oxide, barium strontium titanate (BST), lead zirconate titanate (PZT), zirconium silicate (ZrSiO₄), hafnium silicon oxide (HfSiO₂), hafnium silicon oxynitride (HfSiON), tantalum oxide or a combination of the above materials. The conductive lines L1/L2/L3 include aluminum or copper.

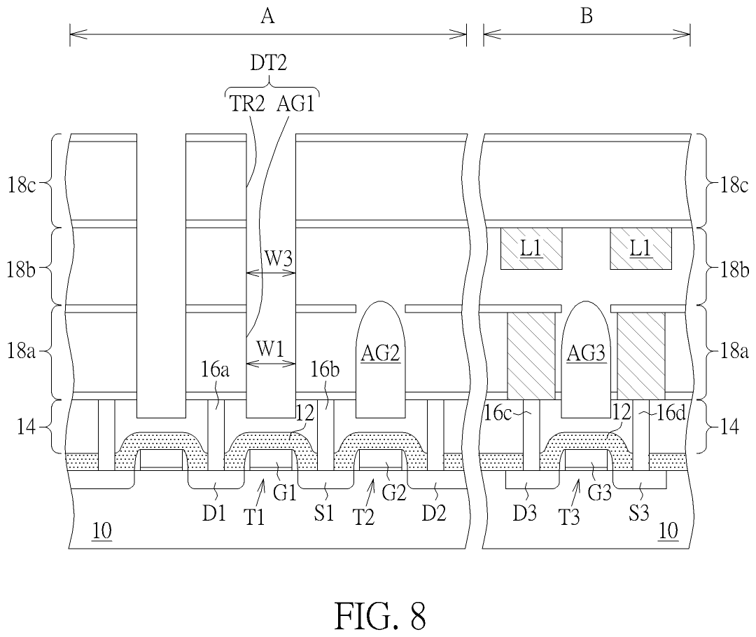

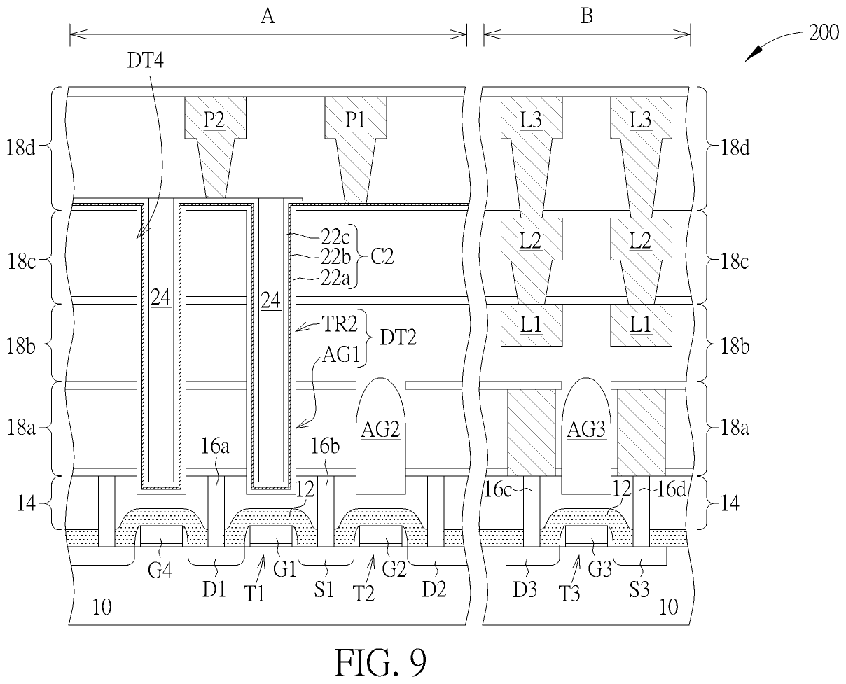

FIG. 8 to FIG. 9 depict a fabricating method of a semiconductor structure with an MIM capacitor according to a second preferred embodiment of the present invention, wherein elements which are substantially the same as those in the first preferred embodiment are denoted by the same reference numerals; an accompanying explanation is therefore omitted. FIG. 8 depicts fabricating steps in continuous of the steps in FIG. 4. As shown in FIG. 8, the second metal interlayer dielectric layer 18c and the dielectric layer 18b are etched to form a trench TR2. The trench TR2 connects to the first air gap AG1, and the trench TR2 and the first air gap AG1 form a deep trench DT2. In the second preferred embodiment, the width W3 of the trench TR2 is the same as the width W1 of the first air gap AG1. As shown in FIG. 9, a bottom electrode 22a, a capacitor dielectric layer 22b and a top electrode 22c are formed to cover the deep trench DT2 and the second metal interlayer dielectric layer 18c. Then, a silicon oxide layer 24 is formed to fill the deep trench DT2. After that, steps the same as those shown in the first fabricating steps are performed. For example, the bottom electrode 22a, the capacitor dielectric layer 22b and the top electrode 22c in the circuit region B are removed and part of the top electrode 22c in the capacitor region A is removed to form a MIM capacitor C2. Subsequently, the third metal interlayer dielectric layer 18d, the bottom electrode plug P1, a top electrode plug P2 and conductive lines L3 are formed. Now, a semiconductor structure 200 with an MIM capacitor is completed.

FIG. 7 depicts a semiconductor structure with an MIM capacitor according to the first preferred embodiment.

A semiconductor structure 100 with an MIM capacitor includes a first transistor T1 and a second transistor T2. The first transistor T1 and the second transistor T2 are disposed on a substrate 10. The substrate 10 includes a silicon substrate, a germanium substrate, a gallium arsenide substrate, a silicon germanium substrate, an indium phosphide substrate, a gallium nitride substrate, a silicon carbide substrate or a silicon-on-insulator substrate. The second transistor T2 is adjacent to the first transistor T1. The first transistor T1 includes a first gate G1, a first source S1 and a first drain D1. The first source S1 and the first drain D1 are respectively embedded in the substrate 10 at two sides of the first gate G1. The second transistor T2 includes a second gate G2, the first source S1 and a second drain D2. The first source S1 and the second drain D2 are respectively disposed in the substrate 10 at two sides of the second gate G2. That is, the first source S1 is a common source of the first transistor T1 and the second transistor T2. An interlayer dielectric layer 14 covers the first transistor T1 and the second transistor T2. A first source plug 16b penetrates the interlayer dielectric layer 14 and contacts the first source S1. A first drain plug 16a penetrates the interlayer dielectric layer 14 and contacts the first drain D1. A first metal interlayer dielectric layer 18a, a dielectric layer 18b, a second metal interlayer dielectric layer 18c and a third metal interlayer dielectric layer 18d cover the interlayer dielectric layer 14 from bottom to top. An MIM capacitor C1 is disposed in the interlayer dielectric layer 14, the first metal interlayer dielectric layer 18a, the dielectric layer 18b and the second metal interlayer dielectric layer 18c. A part of the MIM capacitor C1 is sandwiched between the first source plug 16b and the first drain plug 16a. The MIM capacitor C1 includes a bottom electrode 22a, a capacitor dielectric layer 22b and a top electrode 22c. In details, the MIM capacitor C1 is disposed in a deep trench DT1. The deep trench DT1 is disposed in the interlayer dielectric layer 14, the first metal interlayer dielectric layer 18a, the dielectric layer 18b and the second metal interlayer dielectric layer 18c. The end of the deep trench DT1 is located in the interlayer dielectric layer 14 and the end is on the first gate G1 of the first transistor T1. The bottom electrode 22a, the capacitor dielectric layer 22b and the top electrode 22c cover the deep trench DT1 in sequence. Since the end of the deep trench DT1 is disposed at the interlayer dielectric layer 14 and there is the etching stop layer 12 between the deep trench DT1 and the first gate G1, therefore, the operation of the MIM capacitor C1 will not affect the operation of the first transistor T1. A second air gap AG2 is disposed in the interlayer dielectric layer 14 and the first metal interlayer dielectric layer 18a and the second air gap AG2 is disposed on the second gate G2 of the second transistor T2. Notably, the second air gap AG2 and the lower half of the deep trench DT1 are formed simultaneously by using the same process, so the bottom of the second air gap AG2 and the bottom of the deep trench DT1 are aligned with each other.

Moreover, please refer to FIG. 3, FIG. 5 and FIG. 7. Since the deep trench DT1 is composed of the first air gap AG1 formed in the step of FIG. 3 and the trench TR1 formed in the step of FIG. 5, the trench TR1 connects to the first air gap AG1. The trench TR1 is disposed on the first air gap AG1. The width W2 of the trench TR1 is greater than the width W1 of the first air gap AG1. Therefore, the bottom of the trench TR1 and the opening of the first air gap AG1 form a second stepped profile 26b. The second stepped profile 26 causes the MIM capacitor C1 which conformally contacts the sidewall of the deep trench DT1 to form the first stepped profile 26a. The first stepped profile 26a covers and contacts the second stepped profile 26b.

In addition, another deep trench DT3 can be disposed on one side of the deep trench DT1. The fabricating method of deep trench DT3 is the same as that of deep trench DT1. The bottom electrode 22a, the capacitor dielectric layer 22b and the top electrode 22c can continuously extend from the deep trench DT1 into the deep trench DT3 to make the MIM capacitor C1 in both the deep trench DT1 and the deep trench DT3. The bottom of deep trench DT1 and the bottom of deep trench DT3 are respectively located directly on one gate. Specifically speaking, the deep trench DT1 is disposed directly on the first gate G1, the deep trench DT3 is disposed directly on the fourth gate G4, and the fourth gate G4 is disposed on one side of the first gate G1.

FIG. 9 depicts a semiconductor structure with an MIM capacitor according to a second preferred embodiment. The difference between the MIM capacitor in the first preferred embodiment and the second preferred embodiment is that the MIM capacitor C2 does not have a stepped profile. Please also refer to FIG. 8. This is because in the second preferred embodiment, the width W3 of the trench TR2 is the same as the width W1 of the first air gap AG1, and this makes no turning at the sidewalls of deep trench DT2. Please refer to FIG. 9 again. Similarly, another deep trench DT4 can be disposed on one side of the deep trench DT2. The deep trench DT4 is located directly on the fourth gate G4. The bottom electrode 22a, the capacitor dielectric layer 22b and the top electrode 22c may continuously extend from the deep trench DT3 into the deep trench DT4.

Resistance-capacitance delay (RC delay) often occurs at transistors used as radio frequency switching devices. Therefore, an air gap is disposed on the gate of the transistor to reduce the resistance-capacitance delay. The present invention combines an air gap and a trench process for the MIM capacitor to form a deep trench to accommodate an MIM capacitor. Compared with the deep trench of the traditional MIM capacitor, the deep trench of the present invention has a larger length. In this way, the area of the MIM capacitor is increased, thereby increasing the capacitance of the MIM capacitor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure with a metal-insulator-metal (MIM) capacitor, comprising:
a first transistor, wherein the first transistor comprises a source and a drain;
an interlayer dielectric layer covering the first transistor;
a source plug penetrating the interlayer dielectric layer and contacting the source;
a drain plug penetrating the interlayer dielectric layer and contacting the drain;
a metal interlayer dielectric layer covering the interlayer dielectric layer; and
an MIM capacitor disposed in the interlayer dielectric layer and the metal interlayer dielectric layer.

2. The semiconductor structure with an MIM capacitor of claim 1, wherein the MIM capacitor is sandwiched between the source plug and the drain plug.

3. The semiconductor structure with an MIM capacitor of claim 1, further comprising a deep trench disposed in the metal interlayer dielectric layer and the interlayer dielectric layer, wherein the MIM capacitor comprises a bottom electrode, a capacitor dielectric layer and a top electrode covering the deep trench in sequence.

4. The semiconductor structure with an MIM capacitor of claim 1, wherein an end of the deep trench is disposed in the interlayer dielectric layer and the end is disposed directly above a first gate of the first transistor.

5. The semiconductor structure with an MIM capacitor of claim 1, further comprising:
a second transistor disposed adjacent to the first transistor, wherein the interlayer dielectric layer and the metal interlayer dielectric layer cover the second transistor; and
an air gap disposed in the interlayer dielectric layer and the metal interlayer dielectric layer and disposed directly above a second gate of the second transistor.

6. A semiconductor structure with a metal-insulator-metal (MIM) capacitor, comprising:
a first transistor; and
an MIM capacitor disposed above the first transistor, wherein the MIM capacitor comprises a first stepped profile.

7. The semiconductor structure with an MIM capacitor of claim 6, further comprising:
an interlayer dielectric layer covering the first transistor;
a metal interlayer dielectric layer covering the interlayer dielectric layer; and
a deep trench disposed in the metal interlayer dielectric layer and the interlayer dielectric layer.

8. The semiconductor structure with an MIM capacitor of claim 7, wherein the deep trench comprises a trench and a first air gap, the trench is connected to the first air gap, the trench is disposed on the first air gap, and a width of the trench is greater than a width of the first air gap.

9. The semiconductor structure with an MIM capacitor of claim 8, wherein a bottom of the trench and an opening of the first air gap form a second stepped profile.

10. The semiconductor structure with an MIM capacitor of claim 8, wherein the MIM capacitor contacts a sidewall of the deep trench.

11. The semiconductor structure with an MIM capacitor of claim 6, further comprising:
an interlayer dielectric layer covering the first transistor;
a metal interlayer dielectric layer covering the interlayer dielectric layer;
a second transistor disposed adjacent to the first transistor, wherein the interlayer dielectric layer and the metal interlayer dielectric layer cover the second transistor; and
a second air gap disposed in the interlayer dielectric layer and the metal interlayer dielectric layer and disposed directly above a gate of the second transistor.

12. A fabricating method of a semiconductor structure with a metal-insulator-metal (MIM) capacitor, comprising:
provide a transistor, wherein an interlayer dielectric layer and a first metal interlayer dielectric layer cover the transistor from bottom to top;
etching the first metal interlayer dielectric layer and the interlayer dielectric layer to form a recess on a gate of the transistor;
forming a dielectric layer to fill part of the recess and the dielectric layer sealing up an opening of the recess to form an air gap;
forming a second metal interlayer dielectric layer covering the first metal interlayer dielectric layer;
etching the second interlayer dielectric layer and the dielectric layer to form a trench, wherein the trench connects the air gap, and the trench and the air gap form a deep trench; and
forming an MIM capacitor to fill in the deep trench.

13. The fabricating method of a semiconductor structure with an MIM capacitor of claim 12, wherein a width of the trench is greater than a width of the air gap.

14. The fabricating method of a semiconductor structure with an MIM capacitor of claim 12, wherein the first transistor further comprises a source and a drain, a source plug penetrates the interlayer dielectric layer and contacts the source, a drain plug penetrates the interlayer dielectric layer and contacts the drain, and the MIM capacitor is sandwiched between the source plug and the drain plug.

15. The fabricating method of a semiconductor structure with an MIM capacitor of claim 11, further comprising an etching stop layer covering and contacting the transistor, the interlayer dielectric layer covering and contacting the etching stop layer, and an end of the deep trench being disposed in the interlayer dielectric layer.
